(19) United States
(12) Patent Application Publication
(10) Pub. No.: US 2024/0087772 A1
(43) Pub. Date: Mar. 14, 2024

(54) SHIELDING TAPE, SHIELDING MEMBER, AND WIRE HARNESS

(71) Applicant: Yazaki Corporation, Tokyo (JP)

(72) Inventor: Harutake SATOH, Makinohara-shi (JP)

(73) Assignee: Yazaki Corporation, Tokyo (JP)

(21) Appl. No.: 18/448,617

(22) Filed: Aug. 11, 2023

(30) Foreign Application Priority Data
Sep. 8, 2022 (JP) 2022-143079

(51) Int. Cl. H01B 7/18; B60R 16/02; H01B 7/00; H05K 9/00

(52) U.S. Cl. CPC H01B 7/188; B60R 16/0215; H01B 7/0045; H05K 9/0098

(57) ABSTRACT

A shielding tape includes a tape material having an adhesive surface, and a thin metal film adhered to the adhesive surface. The thin metal film adheres to the adhesive surface while leaving a region where the adhesive surface is exposed on at least one end portion of the tape material in a width direction.

### CROSS-REFERENCE TO RELATED APPLICATIONS

This application is based on and claims priority under 35 USC 119 from Japanese Patent Application No. 2022-143079 filed on Sep. 8, 2022, the entire content of which is incorporated herein by reference.

### TECHNICAL FIELD

The present invention relates to a shielding tape and a shielding member used for an electric wire of a vehicle or the like, and a wire harness to be routed in a vehicle or the like.

### BACKGROUND ART

A wire harness routed in a vehicle includes plural bundled electric wires such as electric wires for electric power and electric wires for communication. The electric wires are covered with a shielding member at a portion where electromagnetic interference may occur between the electric wires and an auxiliary device mounted on the vehicle or another wire harness. For example, Patent Literature 1 discloses that a metal foil tape is spirally wound around an outer periphery of an electric wire bundle including a drain wire. After the metal foil tape is wound around the electric wire bundle, an adhesive tape is further wound around an outer periphery of the metal foil tape to prevent displacement.

In addition, a wire harness is covered with a protective member such as a protector to protect electric wires from interference with an external interfering material such as another component or a vehicle body due to vibration caused by traveling of a vehicle. For example, Patent Literature 2 discloses a wire harness in which an electric wire bundle is wrapped with a shielding exterior material having a metal film on one surface of a resin sheet, and both ends of the electric wire bundle are fixed by an adhesive tape.

### CITATION LIST

### Patent Literature

Patent Literature 1: JP2000-251548A
Patent Literature 2: JP2015-72884A

### SUMMARY OF INVENTION

In the shielded electric wires described in Patent Literature 1, it is necessary to wind the metal foil tape around the electric wire bundle, which takes time for the work process. When the adhesive tape is wound around the outer periphery of the metal foil tape, time required for the work process further increases.

Similarly, in the wire harness described in Patent Literature 2, since the electric wire bundle is wrapped with the shielding exterior material and both the end portions are fixed by the adhesive tape, time required for the work process is long.

The present invention is made in view of the above circumstances, and an object of the present invention is to provide a shielding tape and a shielding member that can easily provide an electric wire with a shielding function and also function as a protective material for the electric wire, and a wire harness to be routed in a vehicle or the like.

To achieve the above object, the shielding tape, the shielding member, and the wire harness to be routed in a vehicle or the like according to the present invention have the following features.

A shielding tape of the present disclosure includes a tape material having an adhesive surface, and a thin metal film adhering to the adhesive surface. The thin metal film adheres to the adhesive surface while leaving a region where the adhesive surface is exposed on at least one end portion of the tape material in a width direction.

Further, in a shielding member of the present disclosure, a pair of the shielding tapes described above are arranged such that the thin metal films of the shielding tapes face each other, the exposed adhesive surface of one of the shielding tapes adheres to the other one of the shielding tapes, and the pair of thin metal films that face each other define a shielding space into which an object to be shielded is inserted.

Furthermore, a wire harness of the present disclosure includes the above shielding member, and an electric wire bundle including a plurality of electric wires, the electric wire bundle being the object to be shielded. One electric wire of the plurality of electric wires is a drain wire in which a coating is removed and a conductor is exposed.

It is possible to provide a shielding tape and a shielding member that can easily provide an electric wire with a shielding function and also function as a protective material for the electric wire, and a wire harness to be routed in a vehicle or the like.

The present invention is briefly described above. Details of the present invention can be further clarified by reading modes for carrying out the invention to be described below (hereinafter referred to as “embodiments”) with reference to the accompanying drawings.

### BRIEF DESCRIPTION OF DRAWINGS

FIG. 1 is a plan view of a wire harness to which a shielding member according to an embodiment is attached;

FIG. 2 is a plan view of a shielding tape according to the present embodiment;

FIG. 3 shows a manufacturing process of the shielding member according to the present embodiment;

FIG. 4 is a cross-sectional view showing the shielding member according to the present embodiment;

FIG. 5 is a plan view showing another example of the shielding member;

FIG. 6 is a plan view showing an example 1 of the wire harness;

FIG. 7 is a plan view showing an example 2 of the wire harness;

FIG. 8 shows a manufacturing process of a wire harness having a branch portion;

FIG. 9 is a plan view showing the wire harness having the branch portion; and

FIG. 10 is a plan view showing a wire harness having a branch portion in the related art.

### DESCRIPTION OF EMBODIMENTS

A specific embodiment of the present invention will be described below with reference to the drawings.

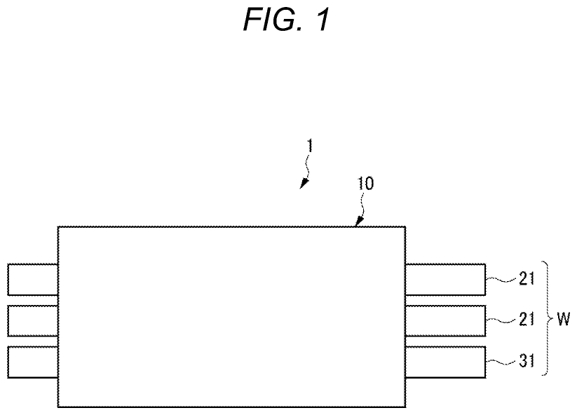

FIG. 1 is a plan view of a wire harness to which a shielding member according to an embodiment is attached.

As shown in FIG. 1, a wire harness 1 according to the present embodiment includes a shielding member 10 and an electric wire bundle W. The electric wire bundle W includes plural wires 21 and a drain wire 31 in which a part of a coating is removed and a conductor is exposed, and has a predetermined section shielded by the shielding member 10.

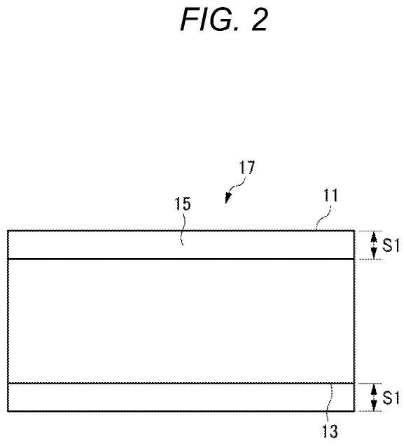

As shown in FIG. 2, a shielding tape 17 constituting the shielding member 10 includes a tape material 11 having an adhesive surface 15 on one surface side, and a metal foil 13.

The metal foil 13 is formed of a thin metal film such as an aluminum foil or a copper foil. Instead of the metal foil, a braid may adhere to the tape material 11.

The metal foil 13 is formed in such a size that the adhesive surface 15 having a width S1 is exposed at both end portions of the tape in a width direction. In the metal foil 13, the adhesive surface 15 may be exposed at only one end portion of the tape in the width direction. The exposed adhesive surface 15 is used when two shielding tapes 17 adhere to each other as to be described later. When the adhesive surface 15 is exposed at only one end portion of the tape in the width direction, a pair of shielding tapes 17 adhere to each other such that the exposed adhesive surfaces 15 of the pair of shielding tapes 17 are respectively located on one side and the other side in the width direction.

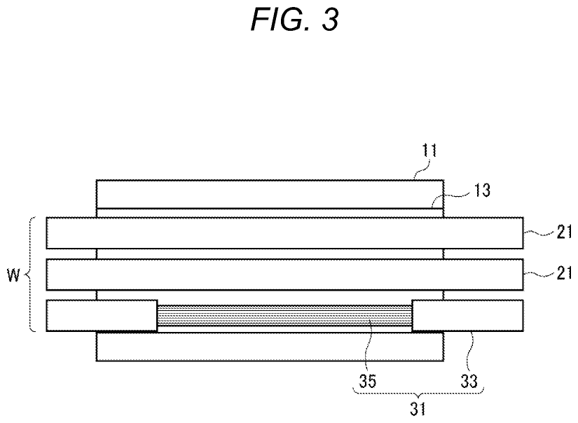

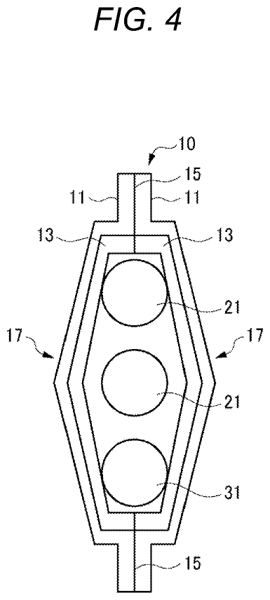

FIG. 3 shows a manufacturing process of a shielding member according to the present embodiment. FIG. 4 is a cross-sectional view illustrating the shielding member according to the present embodiment.

In a manufacturing process of the wire harness 1 including the shielding member 10, two shielding tapes 17 having substantially the same size are prepared, and the electric wire bundle W is placed on the metal foil 13 of one of the two shielding tapes 17. At this time, a conductor 35 of the drain wire 31 provided in the electric wire bundle W comes into contact with and becomes electrically connected to the metal foil 13. Accordingly, when the wire harness 1 is routed at a predetermined portion of a vehicle, the metal foil 13 is connected to the ground through the drain wire 31.

Next, the other one of the two prepared shielding tapes 17 overlaps the one of the two shielding tapes 17 and adheres thereto by the exposed adhesive surface 15. Accordingly, as shown in FIG. 4, the shielding member 10 is completed while defining a space in which the electric wire bundle W is covered and shielded by a pair of metal foils 13.

In this way, the shielding member 10 having a shielding function and a protective function for the electric wire bundle W can be formed by simply allowing the two shielding tapes 17 to adhere to each other in a desired region of the electric wire bundle W. Accordingly, it is neither necessary to spirally wind a metal foil tape or a protective tape in a longitudinal direction of the electric wire bundle W as in the related art, nor to wind a shielding exterior material around the electric wire bundle and separately fix the shielding exterior material with an adhesive tape. Accordingly, the shielding member 10 including the shielding tape 17 according to the present embodiment can remarkably improve the work efficiency. The shielding tape 17 may be cut not only to a predetermined length in advance, but also in a freely selected position during work. In this case, the shielding function and the protective function can be provided over a desired position of the wire harness 1. Accordingly, the shielding member 10 can be formed at a corresponding place using the elongated shielding tape 17 even when the shielding members 10 having plural types of lengths are not prepared in advance.

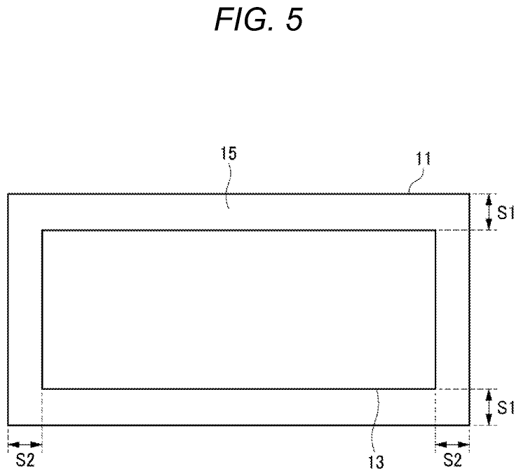

FIG. 5 is a plan view showing another example of the shielding member.

In the shielding tape 17 shown in FIG. 5, the metal foil 13 is formed in such a size that the adhesive surface 15 having the width S1 is exposed at both end portions of the tape in the width direction and the adhesive surface 15 having a length S2 is exposed at both end portions of the tape in a longitudinal direction.

When the shielding member 10 is constituted by the shielding tape 17, not only both the end portions of the two shielding tapes 17 in the width direction can be bonded, but also both the end portions in the longitudinal direction can be bonded to the electric wire bundle W. Accordingly, foreign matters such as dust can be prevented from entering from both end portions of the shielding member 10.

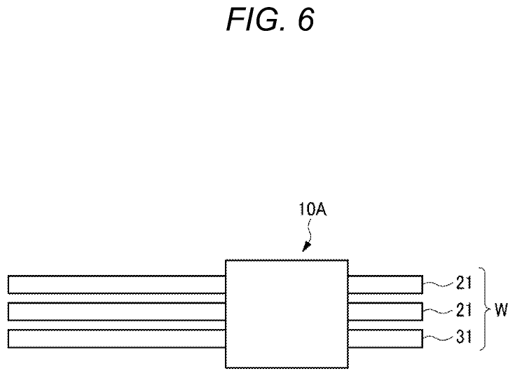

FIG. 6 is a plan view showing an example 1 of the wire harness. As shown in this example, a shielding member 10A can easily provide the shielding function and the protective function to a necessary portion alone of a wire harness by simply shortening a length of the shielding tape 17.

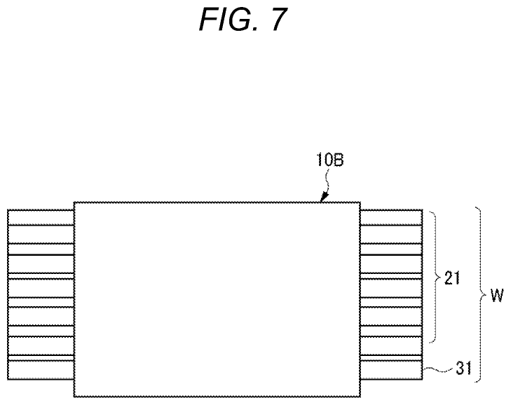

FIG. 7 is a plan view showing an example 2 of the wire harness. As shown in this example, a shielding member 10B can cope with an increase in the number of electric wires provided in an electric wire bundle to be shielded by simply changing widths of the tape material 11 and the metal foil 13 to be prepared. Regarding this, when an electric wire bundle is protected by a protector having a shielding function in the related art, it is necessary to increase a size of the protector. In addition, as the electric wire bundle becomes thicker, the required production quantity of protectors matching with the size of the electric wire bundle generally decreases. Accordingly, the manufacturing cost of the protector increases remarkably. In contrast, the shielding member 10B including the shielding tape 17 according to the present embodiment can cope with various electric wire bundles while preventing an increase in cost. Further, a metal foil of the shielding member 10B can be connected to the ground when only one drain wire is routed in the shielding member 10B. Accordingly, it is not necessary to prepare a plurality of drain wires, which contributes to weight reduction of a wire harness.

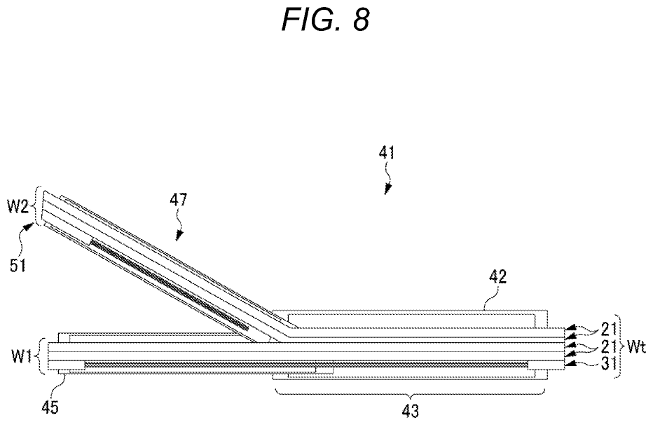

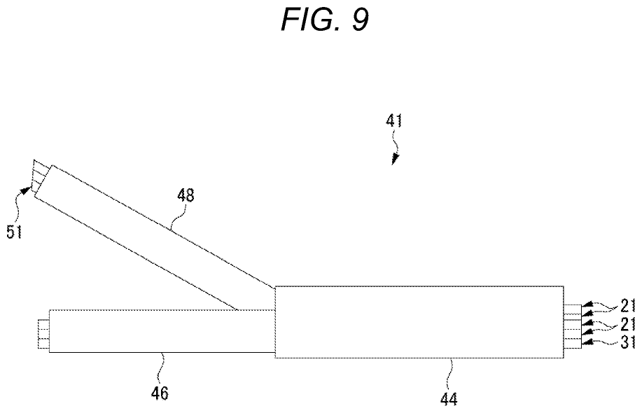

FIG. 8 shows a manufacturing process of a wire harness having a branch portion. FIG. 9 is a plan view showing the wire harness having the branch portion.

A branch wire harness 41 includes a first electric wire bundle W1 and a second electric wire bundle W2. The first electric wire bundle W1 and the second electric wire bundle W2 constitute an electric wire bundle Wt at a base end portion 43, and branch from the base end portion 43.

At the base end portion 43, the electric wire bundle Wt is placed on a base end portion shielding tape 42. The first electric wire bundle W1 is placed on a first branch portion shielding tape 45. The second electric wire bundle W2 is placed on a second branch portion shielding tape 47. The base end portion shielding tape 42, the first branch portion shielding tape 45, and the second branch portion shielding tape 47 are formed in the same way as the shielding tape 17.

Then, another set of the base end portion shielding tape 42, the first branch portion shielding tape 45, and the second branch portion shielding tape 47 respectively overlap the above-mentioned set. Accordingly, as shown in FIG. 9, a base end portion shielding member 44 covering the electric wire bundle Wt, a first branch portion shielding member 46 covering the first electric wire bundle W1, and a second branch portion shielding member 48 covering the second electric wire bundle W2 are formed.

At this time, as shown in FIG. 8, the drain wire 31 provided in the first electric wire bundle W1 is disposed in the base end portion 43, and a metal foil of the base end portion shielding tape is connected to the ground by the drain wire 31. On the other hand, a drain wire 51 provided in the second electric wire bundle W2 does not extend to the base end portion 43. Accordingly, only one drain wire is disposed in the base end portion 43, so that the entire wire harness can be reduced in size and weight.

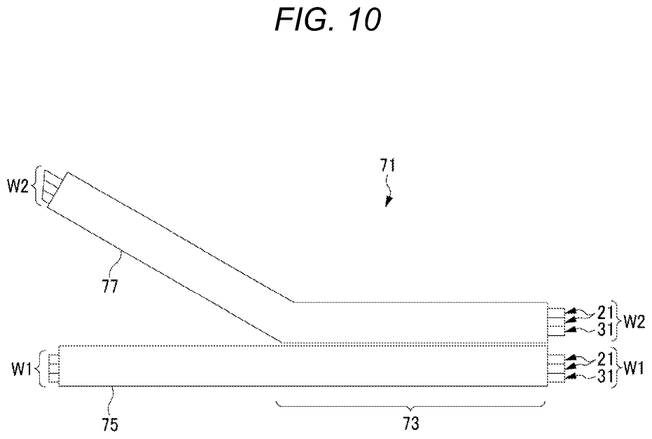

FIG. 10 is a plan view showing a wire harness having a branch portion in the related art.

As shown in FIG. 10, in a branch wire harness 71 having a branch portion in the related art, the electric wire bundles W1, W2 are each shielded and protected by a shielding member such as a protector. As described above, since manufacturing a large protector remarkably increases the cost, the wire bundle W1 and the wire bundle W2 are covered with different shielding members even at a base end portion 73. For this reason, the drain wire 31 is necessary in each of the electric wire bundle W1 and the electric wire bundle W2 even in the base end portion 73. That is, as the number of electric wire bundles increases, it is necessary to dispose the drain wires 31 in the base end portion 73 by the same number as the electric wire bundles, which hinders a reduction in size and weight of a wire harness.

On the other hand, in the branch wire harness 41 according to the present embodiment, even when no special shielding member or protector is prepared, the base end portion shielding member 44 that covers the whole electric wire bundle Wt can be implemented by only one pair of base end portion shielding tapes 42. Accordingly, when one drain wire 31 is routed in the base end portion 43, the metal foil of the base end portion shielding tape 42 can be connected to the ground, and the entire wire harness can be reduced in size and weight.

The present invention is not limited to the above-described embodiment and can be appropriately modified, improved and the like. In addition, materials, shapes, sizes, numbers, arrangement positions and the like of components in the above-described embodiment are freely selected and are not limited as long as the present invention can be implemented.

Here, features of the shielding tape, the shielding member, and the wire harness to be routed in a vehicle or the like according to the above-described embodiment of the present invention will be briefly summarized and listed in the following [1] to [5]. [1] A shielding tape (17) including:

a tape material (11) having an adhesive surface (15); and

a thin metal film (metal foil 13) adhering to the adhesive surface (15), wherein

the thin metal film (metal foil 13) adheres to the adhesive surface (15) while leaving a region where the adhesive surface (15) is exposed on at least one end portion of the tape material (11) in a width direction.

According to the shielding tape having the configuration of [1], by bonding a pair of shielding tapes such that the thin metal films face each other with a simple configuration in which the thin metal film adheres to the adhesive surface of the tape material, an object to be shielded such as an electric wire can be easily provided with a shielding function.

[2] The shielding tape according to [1], wherein

the thin metal film (metal foil 13) adheres to the adhesive surface (15) while leaving a region where the adhesive surface (15) is exposed on both ends of the tape material (11) in a longitudinal direction.

According to the shielding tape having the configuration of [2], not only the pair of shielding tapes can adhere to each other, but also foreign matters such as dust can be prevented from entering from both ends of the pair of shielding tapes in the longitudinal direction.

[3] A shielding member (10, 10A, 10B), wherein a pair of the shielding tapes (17) according to [1] are arranged such that the thin metal films (metal foils 13) of the shielding tapes (17) face each other,

the exposed adhesive surface (15) of one of the shielding tapes (17) adheres to the other one of the shielding tapes (17), and

the pair of thin metal films (metal foils 13) that face each other define a shielding space into which an object to be shielded (electric wire bundle W) is inserted.

According to the shielding member having the configuration of [3], the shielding member can be implemented by simply allowing two shielding tapes each having a simple configuration to adhere to each other. In addition, shielding members having various sizes and lengths can be prepared by simply changing a length and a width of the shielding tape, and the shielding members can easily adhere to the electric wire bundle.

[4] A wire harness including the shielding member (10, 10A, 10B) according to [3]; and

an electric wire bundle (W) including plural electric wires, the electric wire bundle being the object to be shielded, wherein

one electric wire of the plural electric wires is a drain wire (31) in which a coating is removed and a conductor is exposed.

According to the wire harness having the configuration of [4], a desired section of the electric wire bundle is shielded and protected by the shielding member. Accordingly, when a wire harness is routed, for example, in the vicinity of a generation source of electromagnetic noise or in a position where the wire harness may interfere with another interference material of the vehicle, an electric wire bundle located in these sections can be protected. In addition, since the size and the length of the shielding member can be easily changed, even when a routing path of a wire harness changes, the design of the wire harness changes, or a position of another interference material of the vehicle changes, the shielding member can be easily disposed in an appropriate position without any cost.

[5] The wire harness according to [4], wherein

the wire harness is a branch wire harness (41) including a first electric wire bundle (W1) and a second electric wire bundle (W2) branching from the first electric wire bundle (W1),

the shielding member includes a base end portion shielding member (44) that shields a base end portion (43) in which the first electric wire bundle and the second electric wire bundle are bundled, and a first branch shielding member (46) and a second branch shielding member (48) that respectively shield the branch first electric wire bundle (W1) and the branch second electric wire bundle (W2), and

a drain wire (31) provided in the first electric wire bundle (W1) is disposed in the base end portion shielding member (44), and a drain wire (51) provided in the second electric wire bundle (W2) does not extend to the base end portion (43).

According to the wire harness having the configuration of [5], all the electric wire bundles in the base end portion of the branch wire harness can be covered by a pair of shielding members. Accordingly, when one drain wire is routed in the base end portion, the metal foil of the base end portion shielding tape 42 can be connected to the ground, and the entire wire harness can be reduced in size and weight.

What is claimed is:

1. A shielding tape comprising:
a tape material having an adhesive surface; and
a thin metal film adhering to the adhesive surface, wherein
the thin metal film adheres to the adhesive surface while leaving a region where the adhesive surface is exposed on at least one end portion of the tape material in a width direction.

2. The shielding tape according to claim 1, wherein
the thin metal film adheres to the adhesive surface while leaving a region where the adhesive surface is exposed on both ends of the tape material in a longitudinal direction.

3. A shielding member, wherein
a pair of the shielding tapes according to claim 1 are arranged such that the thin metal films of the shielding tapes face each other,
the exposed adhesive surface of one of the shielding tapes adheres to the other one of the shielding tapes, and
the pair of thin metal films that face each other define a shielding space into which an object to be shielded is inserted.

4. A wire harness comprising:
the shielding member according to claim 3; and
an electric wire bundle including a plurality of electric wires, the electric wire bundle being the object to be shielded, wherein
one electric wire of the plurality of electric wires is a drain wire in which a coating is removed and a conductor is exposed.

5. The wire harness according to claim 4, wherein
the wire harness is a branch wire harness including a first electric wire bundle and a second electric wire bundle branching from the first electric wire bundle,
the shielding member includes a base end portion shielding member that shields a base end portion in which the first electric wire bundle and the second electric wire bundle are bundled, and a first branch shielding member and a second branch shielding member that respectively shield the branch first electric wire bundle and the branch second electric wire bundle, and
a drain wire provided in the first electric wire bundle is disposed in the base end portion shielding member, and a drain wire provided in the second electric wire bundle does not extend to the base end portion.
